(19) United States
(12) Patent Application Publication
(10) Pub. No.: US 2025/0299079 A1
(43) Pub. Date: Sep. 25, 2025

(54) PERIODIC FILTERS FOR QUANTUM COMMUNICATION LINKS

(71) Applicant: INTERNATIONAL BUSINESS MACHINES CORPORATION, ARMONK, NY (US)

(72) Inventors: Muir Kumph, Croton on Hudson, NY (US); Timothy Phung, Milpitas, CA (US)

(21) Appl. No.: 18/616,108

(22) Filed: Mar. 25, 2024

(51) Int. Cl. G06N 10/40; H01P 3/00; H03H 7/01; H03H 7/06; H10N 69/00

(52) U.S. Cl. CPC G06N 10/40; H01P 3/00; H03H 7/06; H10N 69/00; H03H 2007/013

(57) ABSTRACT

A quantum communication link includes a first unit section having an inner conductor with a predetermined impedance based on a capacitance and an inductance. A second unit section has an inner conductor with a predetermined impedance based on a capacitance and an inductance. The first unit section and the second unit sections are alternatingly repeated to result in a cable structured as a periodic filter having a selected passband and a selected stopband. A first qubit coupled to a first end of the cable and a second qubit coupled to a second end of the cable.

### BACKGROUND

### Technical Field

The present disclosure generally relates to superconducting devices, and more particularly, to interconnecting qubits while avoiding frequency collisions.

### Description of the Related Art

Superconducting quantum computing is an implementation of a quantum computer in superconducting electronic circuits. Quantum computation studies the application of quantum phenomena for information processing and communication. Various models of quantum computation exist, and the most popular models include the concepts of qubits and quantum gates. A qubit is a generalization of a bit that has two possible states, but can be in a quantum superposition of both states. A quantum gate is a generalization of a logic gate, however the quantum gate describes the transformation that one or more qubits will experience after the gate is applied on them, given their initial state. Various quantum phenomena, such as superposition and entanglement, do not have analogs in the world of classical computing and therefore may involve special structures, techniques, and materials.

### SUMMARY

According to various embodiments, a method an interconnect system, and a quantum communication link are provided. There is first unit section having an inner conductor with a predetermined impedance based on a capacitance and an inductance. There is a second unit section having an inner conductor with a predetermined impedance based on a capacitance and an inductance. The first unit section and the second unit sections are alternatingly repeated to result in a cable structured as a periodic filter having a selected passband and a selected stopband. A first qubit is coupled to a first end of the cable. A second qubit is coupled to a second end of the cable.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates an example architecture of a quantum computing system having quantum communication links, consistent with an illustrative embodiment.

FIG. 2 is an example cable implemented as a periodic filter, consistent with an illustrative embodiment.

FIG. 3 illustrates an example filter unit that can be used to implement a high (H) impedance low pass filter or a low (L) impedance low pass filter of FIG. 2, to ultimately construct an overall stepped impedance filter, consistent with an illustrative embodiment.

FIG. 4 provides a view of a portion of the cable having alternating sections of high impedance and low impedance, consistent with an illustrative embodiment.

FIG. 5 provides a frequency response of the stepped impedance filter of FIG. 2, consistent with an illustrative embodiment.

FIG. 6A provides a log plot of the performance of the stepped impedance filter of FIG. 2, consistent with an illustrative embodiment.

FIG. 6B, illustrates qubits interconnected by a cable implemented as a stepped impedance filter, consistent with an illustrative embodiment.

FIG. 7 is an alternative transmission cable implemented as a series of capacitively coupled resonators, consistent with an illustrative embodiment.

FIG. 8 provides an example resonator, consistent with an illustrative embodiment.

FIG. 9 provides a view of a portion of the cable having two sections of having two sections of a cable interconnected via capacitive coupling, consistent with an illustrative embodiment.

FIG. 10 provides a simulation result of a transmission cable, similar to the transmission cable of FIG. 7, consistent with an illustrative embodiment.

FIG. 11 illustrates a transmission cable implemented as a periodic filter using inductance, consistent with an illustrative embodiment.

FIG. 12 provides simulation results of a frequency response of a regular transmission cable, as well as one similar to the transmission cable of FIG. 11, consistent with an illustrative embodiment.

FIG. 13 presents an illustrative process related to reading out signals from a quantum processor, consistent with an illustrative embodiment.

### DETAILED DESCRIPTION

### Technical Advantages and Support

It is to be understood that some of the advantages of the present disclosure are provided herein below. However, a person of ordinary skill in the art will appreciate that additional advantages may exist in addition to those described herein.

According to an embodiment, an interconnect system includes a first unit section having an inner conductor with a predetermined impedance based on a capacitance and an inductance. A second unit section has an inner conductor with a predetermined impedance based on a capacitance and an inductance. The first unit section and the second unit sections are alternatingly repeated to result in a cable structured as a periodic filter having a selected passband and a selected stopband. In this way, qubits can be interconnected with a substantial reduction of crosstalk from other qubits, as well as noise from supporting circuitry.

In one embodiment, which can be combined with the preceding embodiment, each end of the cable structure is connected to a separate qubit. Qubits can be interconnected without noise interference from other qubits and/or neighboring supporting circuitry.

In one embodiment, which can be combined with one or more preceding embodiments, the separate qubits are on separate chips. In this way, qubits from chips that are separate can be interconnected.

In one embodiment, which can be combined with one or more preceding embodiments, the chips are in different cryogenic environments. In this way, different types of qubits and/or qubits that operate in different temperature ranges can be successfully interconnected without interference from other components.

In one embodiment, which can be combined with one or more preceding embodiments, the cable is a coaxial cable. A coaxial cable provides shielding from all sides for the inner conductor discussed herein.

In one embodiment, which can be combined with one or more preceding embodiments, the first unit section and second unit section each have a conducting shield. The conductive shield provides some shielding from neighboring signals. The inner conductor of the first unit section has a width that is smaller than a width of the second unit section. The differences in width allow the impedance of the conductive shield to be adjusted, thereby being able to adjust the unit impedance and ultimate filter effect of each unit section accordingly.

In one embodiment, which can be combined with one or more preceding embodiments, the predetermined impedance of the inner conductor of the first unit section is lower than the predetermined impedance of the inner conductor of the second unit section. In this way, the frequency response of each unit section can be adjusted.

In one embodiment, which can be combined with one or more preceding embodiments, the cable forms a communications channel between two qubits. The cable provides an entanglement between both qubits in the passband region, while rejecting interference from other qubits in the stopband region. The entanglement is enhanced while being more immune from interference from other components.

In one embodiment, which can be combined with one or more preceding embodiments, the stopband covers a frequency range of one or more readout resonators coupled to separate qubits at each end of the cable. By adjusting the stopband to the frequency range of the readout resonators, the fidelity of the qubits is better protected.

In one embodiment, which can be combined with one or more preceding embodiments, the first and second section units are different in structure. The alternately repeated first and second section units provide a stepped impedance filter. The stepped impedance filter can be configured to provide a passband and stop bands in desired frequency ranges.

In one embodiment, which can be combined with one or more preceding embodiments, the first unit section has a gap between the inner conductor and the conducting shield that is larger than a gap between the inner conductor and the conducting shield of the second unit section. The larger gap adjusts its frequency and impedance properties.

In one embodiment, which can be combined with one or more preceding embodiments, the first unit section and the second unit section have a same structure. The first unit section and the second unit section are configured as a resonator. The inner conductor of the first unit section is capacitively coupled to the inner conductor of the second unit section. Such structure provides a bandpass filter that provides approximately 100 dB rejection outside the bandpass region.

In one embodiment, which can be combined with one or more preceding embodiments, the first unit section and the second unit section have a same structure; the first unit section and the second unit section are configured as a resonator; and the first unit section and the second unit section are inductively coupled. In this way, the cable is engineered to act as a bandpass filter.

According to one embodiment, a quantum communication link includes a first unit section having an inner conductor with a predetermined impedance based on a capacitance and an inductance. A second unit section has an inner conductor with a predetermined impedance based on a capacitance and an inductance. The first unit section and the second unit sections are alternatingly repeated to result in a cable structured as a periodic filter having a selected passband and a selected stopband. A first qubit is coupled to a first end of the cable. A second qubit is coupled to a second end of the cable. In this way, qubits can be interconnected with a substantial reduction of crosstalk from other qubits, as well as a reduction in noise from supporting circuitry.

In one embodiment, which can be combined with the preceding embodiment, the separate qubits are on separate chips. In this way, qubits from chips that are separate can be interconnected.

In one embodiment, which can be combined with one or more preceding embodiments, the chips are in different cryogenic environments. In this way, different types of qubits can be successfully interconnected without interference from other components.

In one embodiment, which can be combined with one or more preceding embodiments, the first unit section and second unit section each have a conducting shield. The inner conductor of the first unit section has a width that is smaller than a width of the second unit section. The predetermined impedance of the inner conductor of the first unit section is lower than the predetermined impedance of the inner conductor of the second unit section. The conductive shield provides some shielding from neighboring signals. The inner conductor of the first unit section has a width that is smaller than a width of the second unit section. The differences in width allow the impedance of the conductive shield to be adjusted, thereby being able to adjust the unit impedance and ultimate filter effect of each unit section accordingly.

In one embodiment, which can be combined with one or more preceding embodiments, the cable provides an entanglement between the first qubit and the second qubit in the passband region, while rejecting interference from other qubits in the stopband region. The entanglement is enhanced while being more immune from interference from other components.

In one embodiment, which can be combined with one or more preceding embodiments, the first unit section and the second unit section have a same structure. The first unit section and the second unit section are configured as a resonator. The inner conductor of the first unit section is capacitively or inductively coupled to the inner conductor of the second unit section. The cable is a passband filter. The inductive or capacitive coupling between the resonators facilitates implementation of a bandpass filter, which is able to provide isolation from other components outside the range of the bandpass frequency range.

According to an embodiment, a method of providing a quantum communication link includes providing a first unit section having an inner conductor with a predetermined impedance based on a capacitance and an inductance. A second unit section having an inner conductor with a predetermined impedance based on a capacitance and an inductance is provided. The first unit section and the second unit sections are alternatingly repeated and provide a cable structured as a periodic filter having a selected passband and a selected stopband. A first qubit is coupled to a first end of the cable and a second qubit is coupled to a second end of the cable. In this way, qubits can be interconnected with a substantial reduction of crosstalk from other qubits, as well as a reduction in noise from supporting circuitry.

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, third, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as “lossless,” “superconductor,” “superconducting,” “absolute zero,” which are intended to cover functionality that may not be exactly ideal but is within acceptable margins for a given application. For example, a certain level of loss or tolerance may be acceptable such that the resulting materials and structures may still be referred to by these “idealized” terms.

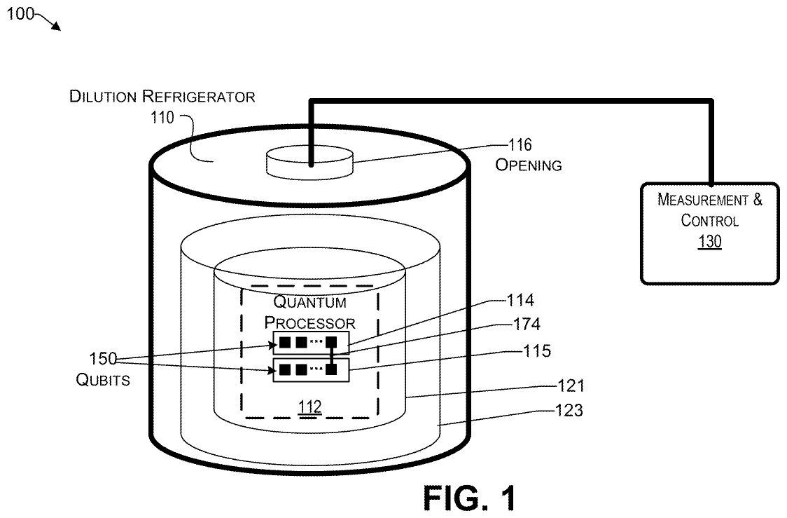

The present disclosure generally relates to superconducting devices, and more particularly, to methods and systems of interconnecting qubits. The electromagnetic energy associated with a qubit can be stored in so-called Josephson junctions and in the capacitive and inductive elements that are used to form the qubit. In one example, to read out the qubit state, a microwave signal is applied to the microwave readout cavity that couples to the qubit at the cavity frequency. The transmitted (or reflected) microwave signal goes through multiple thermal isolation stages and low-noise amplifiers that are used to block or reduce the noise and improve the signal-to-noise ratio. Alternatively, or in addition, a microwave signal (e.g., pulse) can be used to entangle one or more qubits. Much of the process is performed in a cold environment (e.g., in a cryogenic chamber), while the microwave signal of a qubit is ultimately measured at room temperature. An example dilution refrigerator implementing a cryogenic chamber is discussed in more detail later in the context of FIG. 1.

The amplitude and/or phase of the returned/output microwave signal carries information about the qubit state, such as whether the qubit has dephased to the ground or excited state. The microwave signal carrying the quantum information about the qubit state is usually weak (e.g., on the order of a few microwave photons). To measure this weak signal with room temperature electronics (i.e., outside the refrigerated environment), low-noise quantum-limited amplifiers (QLAs), such as Josephson amplifiers and travelling-wave parametric amplifiers (TWPAs), may be used as preamplifiers (i.e., first amplification stage) at the output of the quantum system to boost the quantum signal, while adding the minimum amount of noise as dictated by quantum mechanics, in order to improve the signal to noise ratio of the output chain. In addition to Josephson amplifiers, certain Josephson microwave components that use Josephson amplifiers or Josephson mixers such as Josephson circulators, Josephson isolators, and Josephson mixers can be used in scalable quantum processors.

A qubit system may include one or more readout resonators coupled to the qubit. A readout resonator may be a transmission line that includes a capacitive connection to ground on one side and is either shorted to the ground on the other side, such as for a quarter wavelength resonator, or may have a capacitive connection to ground, such as for a half wavelength resonator, which results in oscillations within the transmission line, with the resonant frequency of the oscillations being close to the frequency of the qubit. For example, the readout resonator affects a pulse coming from the control/measurement instruments at the readout resonator frequency. The pulse acts as a measurement that decoheres the qubit and makes it collapse into a state of “one” or “zero,” thereby imparting a phase shift on that measurement pulse.

Between qubits there may be a coupling resonator, sometimes referred to herein as a coupler resonator or RIP bus, which allows coupling different qubits together in order to realize quantum logic gates. The coupling resonator is typically structurally similar to the readout resonator. However, more complex designs are possible. When a qubit is implemented as a transmon, each side of the coupling resonator is coupled (e.g., capacitively or inductively) to a corresponding qubit by being in adequate proximity to (e.g., the capacitor of) the qubit. Since each side of the coupling resonator has coupling with a respective different qubit, the two qubits are coupled together through the coupling resonator (e.g., RIP bus). In this way, there is mutual interdependence in the state between coupled qubits, thereby allowing a coupling resonator to use the state of one qubit to control the state of another qubit.

Entanglement occurs when the interaction between two qubits is such that the states of the two cannot be specified independently, but can only be specified for the whole system. In this way, the states of two qubits are linked together such that a measurement of one of the qubits, causes the state of the other qubit to collapse.

The ability to include more qubits is salient to being able to realize the potential of quantum computers. Generally, performance increases as temperature is lowered, for example, by reducing the residual thermally-excited state qubit population and decreasing the thermal broadening of the qubit transition frequencies. Accordingly, the lower the temperature, the better for a quantum processor.

It has been determined that to increase the computational power and reliability of a quantum computer, improvements are needed along two main dimensions. First, is the qubit count itself. The more qubits in a quantum processor, the more states can in principle be manipulated and stored. Second is low error rates, which is relevant to manipulate qubit states accurately and perform sequential operations that provide consistent results and not merely unreliable data. Thus, to improve fault tolerance of a quantum computer, a large number of physical qubits should be used to store a logical quantum bit. In this way, the local information is delocalized such that the quantum computer is less susceptible to local errors and the performance of measurements in the qubits' eigenbasis, similar to parity checks of classical computers, thereby advancing to a more fault tolerant quantum bit.

As the number of qubits increases, the cross-talk between its wires becomes more prominent. Classical crosstalk is a phenomenon by which a signal transmitted on one circuit or channel of a transmission system creates an undesired effect in another circuit or channel.

Crosstalk is usually caused by undesired capacitive, inductive, or conductive coupling from one circuit or channel to another. In the context of qubit architectures, crosstalk may occur when one a qubit is driven through its control line and unwanted signal is leaked to other qubits via spurious microwave coupling.

Realizing high fidelity operations on remotely connected devices and modules is salient towards building higher performance quantum processors. Achieving a cleaner channel spectrum can significantly simplify the implementation of a multi-qubit chip featuring a long-distance link. The teachings herein can facilitate different architectures that may use an interconnect whose frequency is tuned over a wide range to accommodate various quantum structures (e.g. flux tunable couplers, gatemons, etc.).

In one aspect, the teachings herein are based on Applicants' insight that directly applying conventional integrated circuit techniques for interacting with computing elements to superconducting quantum circuits may not be effective because of the unique challenges presented by quantum circuits that are not presented in classical computing architectures. Accordingly, embodiments of the present disclosure are further based on recognition that issues unique to quantum circuits have been taken into consideration when evaluating applicability of conventional integrated circuit techniques to building superconducting quantum circuits, and, in particular, to electing methods and architectures used for interacting efficiently with qubits. The techniques described herein may be implemented in a number of ways. Example implementations are provided below with reference to the following figures.

### Example Architecture

FIG. 1 illustrates an example architecture 100 of a quantum computing system having quantum communication links, consistent with an illustrative embodiment. The architecture 100 includes a quantum processor 112 comprising a plurality of chips 114, 115. Each chip may include one or more qubits 150. The quantum processor 112 is located in a refrigeration unit 110, which may be a dilution refrigerator. A dilution refrigerator is a cryogenic device that provides continuous cooling to temperatures typically in and around 10 mK. Most of the physical volume of the architecture 100 is due to the large size of the refrigeration unit 110, sometimes referred to herein as a dilution refrigerator. To reach the near-absolute zero temperatures at which the system operates, the refrigeration unit 110 may use liquid helium as a coolant. The dilution refrigerator 110 can have different temperature zones, which may be configured in a nested fashion, where the zones closer to the bottom/center are colder stages. In various embodiments, the chips can be in a same chamber of different chambers of a dilution refrigerator. In some embodiments, the chips can be in separate dilution refrigerators interconnected by a cable.

There is a measurement and control unit 130 that is outside of the refrigeration unit 110. The measurement and control unit 130 is able to communicate with the quantum processor through an opening 116, sometimes referred to as a bulkhead of the dilution refrigerator 110, that also forms a hermetic seal separating the ambient atmospheric pressure from the vacuum pressure of the cryostat under operation.

To extend the scalability of the quantum systems, long distance interconnects (e.g., tens of centimeter) using channels or cables are essential between qubits 150 and/or modules of qubits, sometimes referred to herein as chips 114, 115. These qubits 150 may be inaccessible by chip-to chip interconnections in view of interconnector constrains and those posed by operation in a cryogenic environment. Chip 114 to chip 115 qubit interconnections involves links between the qubit devices that are similar to the connections between qubit devices that are within a single chip (e.g., intra-chip connections). These intra-chip connections typically have a single or very few microwave modes and are limited in size to be below a predetermined distance (e.g., 30 mm).

In one embodiment, coaxial cables can provide a more appropriate interconnect. A coaxial cable is an electrical cable comprising an inner conductor surrounded by a concentric conducting shield separated by a dielectric (e.g., insulating) material. In an ordinary coaxial cable, due to the boundary conditions of the cable, a set of standing wave modes appear (e.g., spaced at approximately ˜100 MHz for a coaxial cable of ˜1 m length). For example, a standing wave mode, sometimes referred to as a stationary wave, is a wave that oscillates in time but whose peak amplitude profile does not substantially move in space. Stated differently, the wave pattern appears to be stationary or “standing” rather than propagating forward or backward. The peak amplitude of the wave oscillations at any point in space is essentially constant with respect to time, and the oscillations at different points throughout the wave are in phase. Standing waves are characterized by specific modes or patterns of oscillation, each associated with a particular wavelength and frequency. The lowest frequency mode is called the fundamental mode, while higher frequency modes are known as harmonics or overtones.

The dense set of modes in a cable or interconnect can lead to frequency collisions between qubits 150 as well as auxiliary devices, such as couplers, readout resonators, and filters, and ultimately limit the performance of these devices, as well as the qubits 150. For example, these components can operate near the frequency of these modes, leading to frequency collisions. In one aspect, the teachings herein provide methods and systems of interconnects 174 between qubits 150, where the interconnect can be engineered to have particular bandpass and stop-band characteristics, thereby avoiding noise interference from other qubits and/or support circuitry.

While the teachings herein are described with respect to operation in the cryogenic environment of the dilution refrigerator 110, it is contemplated that the present solution can be used as a conduit between different temperature zones of the dilution refrigerator (e.g., 112, 121, 123, etc.), between refrigeration units, as well as between a measurement and control unit 130 and the dilution refrigerator 110.

### Example Structures

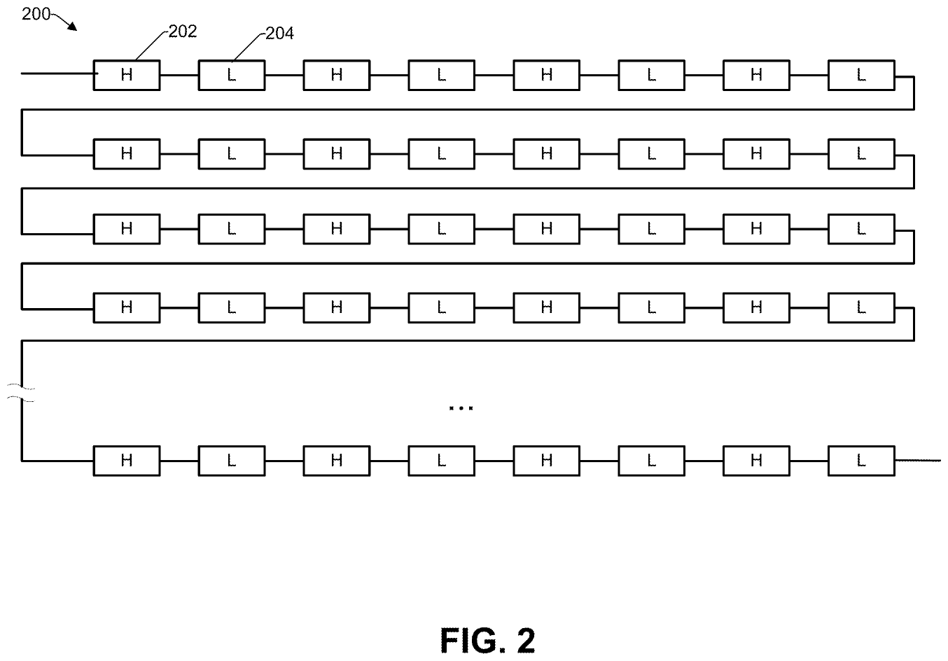

Reference now is made to FIG. 2, which is an example cable implemented as a periodic filter 200, consistent with an illustrative embodiment. For example, the cable 200 has characteristics of a periodic filter because it has a structure having a first unit section 202 (e.g., represented by block H) having a predetermined impedance based on a capacitance and an inductance, and a second unit section 204 (e.g., represented by block L) having a predetermined impedance based on a capacitance and an inductance. The first unit section 202 and the second unit section 204 are alternatingly repeated to result in a cable having a predetermined length. Significantly, the alternatingly repeated first and second unit sections provide a periodic filter that has a predetermined (e.g., specifically engineered) passband and stopband characteristics. Accordingly, the cable is engineered as a stepped impedance filter.

In a stepped impedance filter of FIG. 2, the transmission line sections can have varying characteristic impedances along their length, which creates impedance steps at periodic intervals. For example, FIG. 2 is illustrated as including alternating sections of high (H) and low impedance filters, sometimes referred to herein as first and second unit sections 202, 204. The structure of a stepped impedance filter comprises alternating unit sections of transmission lines with different characteristic impedances. Such structure allows the overall filter (i.e., including all high impedance and low impedance filters) to achieve more complex frequency responses compared to traditional uniform impedance filters. Thus, the “impedance steps” cause reflections and impedance mismatches, resulting in the desired filtering effect.

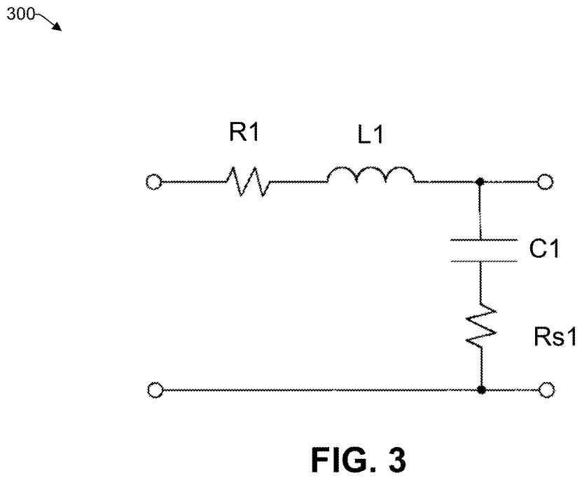

FIG. 3 illustrates an example filter unit 300 that can be used to implement a high (H) impedance low pass filter of the first unit section 202 or a low (L) impedance low pass filter of FIG. 2, to ultimately construct an overall stepped impedance filter, consistent with an illustrative embodiment. In the case of a high (H) impedance low pass filter, the values of at least one of inductance L1, and capacitance C1 (e.g., of the first unit section 202), are chosen to be higher than the values for a low (L) impedance implementation (e.g., of the second unit section 204). When operated in a cryogenic environment, the cable can be operated as a superconductor, thereby reducing the resistance R1 and shunt Resistance Rs1 to substantially zero.

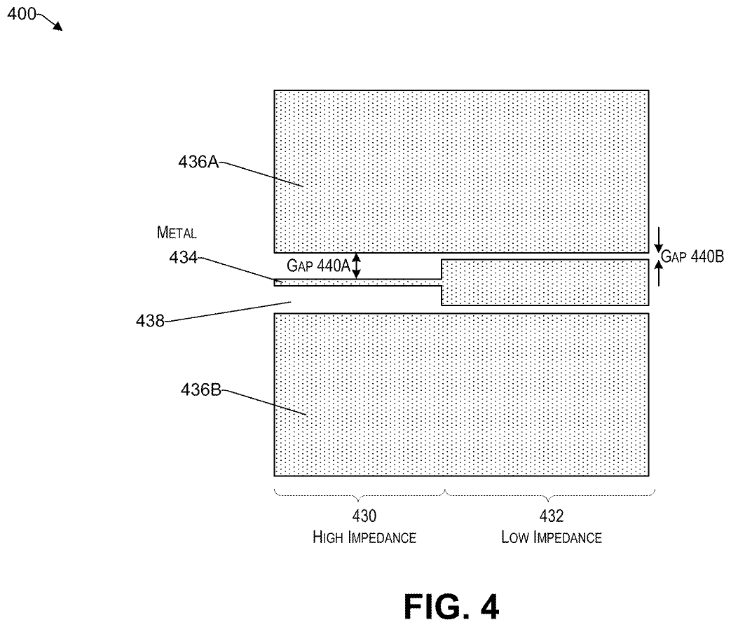

FIG. 4 provides a view of a portion of the cable 400 having alternating sections of high impedance 430 and low impedance 432, consistent with an illustrative embodiment. For example, there is an inner conductor 434, which can be constructed of metal. There is a conducting shield 436A and 436B on each side (e.g., adjacent, above and below, or completely surrounding) the inner conductor 434, which may be constructed of a metal. In one embodiment, the conducting shield 436A/B provides a reference ground, shielding the inner conductor 434.

The high impedance section 430 has a gap 440A between the inner conductor 434 and the conducting shield 436A/B that is larger than the gap 240B of the low impedance section 432. Accordingly, the inner conductor 434 of the high impedance section 430 is thinner than the inner conductor of the low impedance section 432. In one embodiment, the gap between the inner conductor and the conducting shield 436A/B includes a dielectric. Accordingly, by adjusting the width of the inner conductor and the gap, appropriate impedance based on a capacitance (C) and an inductance (L) values can be achieved for each high impedance 430 and low impedance section 432, respectively. In one embodiment, the dielectric 438 material can vary between the high impedance and low impedance sections. The structure of the portion of the cable 400 can be used repeatedly to implement the stepped impedance filter discussed in the context of FIG. 2. In various embodiments, the architecture of FIG. 4 can be implemented, without limitation, as repeated segments of on chip transmission lines, waveguides, transmission lines on flexible substrates, etc.

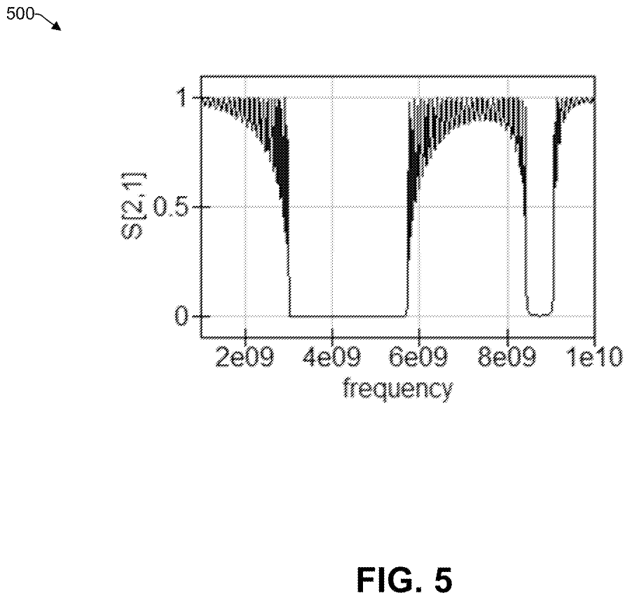

FIG. 5 provides a frequency response 500 of the stepped impedance filter of FIG. 2, consistent with an illustrative embodiment. More specifically, FIG. 5 provides an S21 response of a cable implemented as a stepped impedance filter. The S21 parameter provides a transmission coefficient that measures forward gain. In the case where the measurement ports have the same impedance, the S21 provides a measure of insertion loss. FIG. 5 illustrates that, by virtue of the architecture of the cable of FIG. 2A, there are stop bands approximately between 3 GHz to 5.5 GHZ, and 8.5 GHz and 9 GHz (i.e., after the reentry passband of approximately 6 HGz to 8.3 GHZ). FIG. 5 illustrates that the filtration in the stop band is profound (e.g., nearly no transmission).

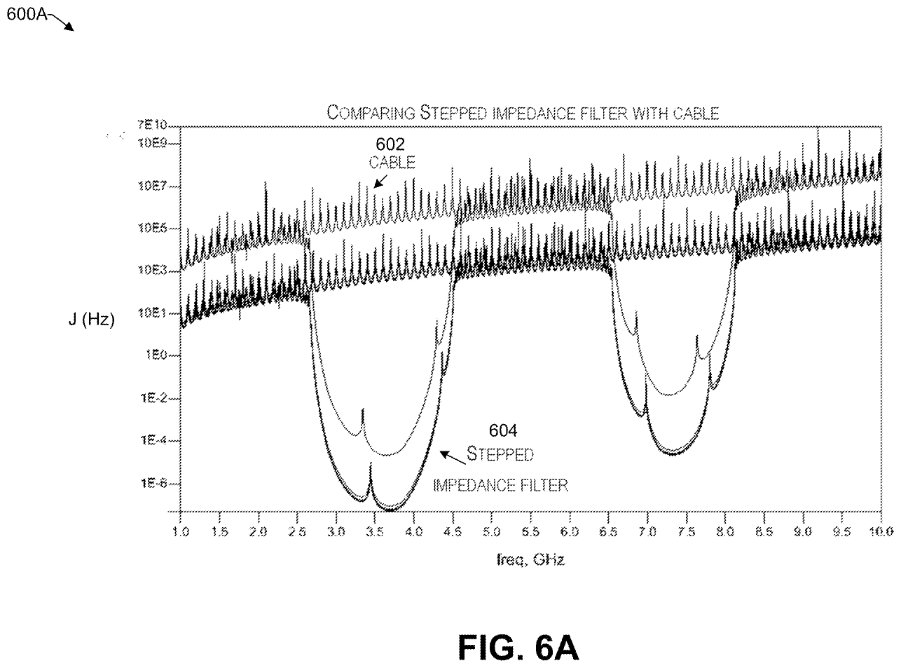

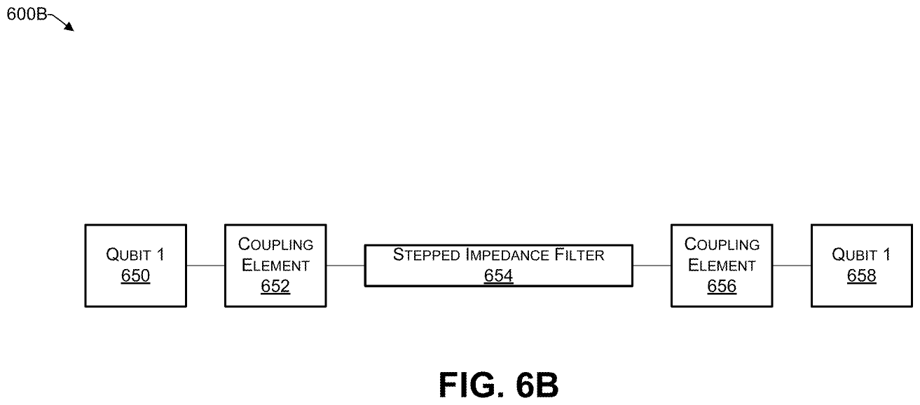

FIG. 6A provides a log plot 600A of the performance of the stepped impedance filter of FIG. 2, consistent with an illustrative embodiment. More specifically, the Example of FIG. 6A illustrates a coupling between two qubits (J). In this regard, reference is made to FIG. 6B, which illustrates qubits interconnected by a cable implemented as a stepped impedance filter, consistent with an illustrative embodiment. As depicted in FIG. 6B. Architecture 600B provides two qubits 650 and 658 that are connected with a cable implemented as a stepped impedance filter 654, which may be similar to that of FIG. 2. Each qubit is coupled to the stepped impedance filter 654 via a corresponding coupling element 652 and 656, respectively.

Returning to FIG. 6A, it illustrates by way of contrast that, while a regular cable 602 of a predetermined length does not include any stop bands, when implemented as a stepped impedance filter 604 according to the teachings herein, stop bands can be created having a desired frequency range. By way of example only and not by way of limitation, the stop bands of the example of FIG. 6A are at approximately 2.6 GHz to 4.5 GHz and 6.5 GHz to 8 GHz, providing approximately 100 dB of rejection compared to the regular cable 602. In this way, the coupling between qubits J (and/or other components of a quantum computing system) can be effectively decoupled.

For example, during operation, when a qubit is active, it can be operated in passband region while enjoying the benefit of being decoupled from other qubits that are idle in the stop band. In this way, active qubits, whether gate-modulated (gatemon) or flux tunable, they are protected without interference from other idle qubits as well as other components that are operated in the stop band region. In another example, readout resonators can be operated in the stopband regions, thereby providing a readout having a superior signal to noise ratio.

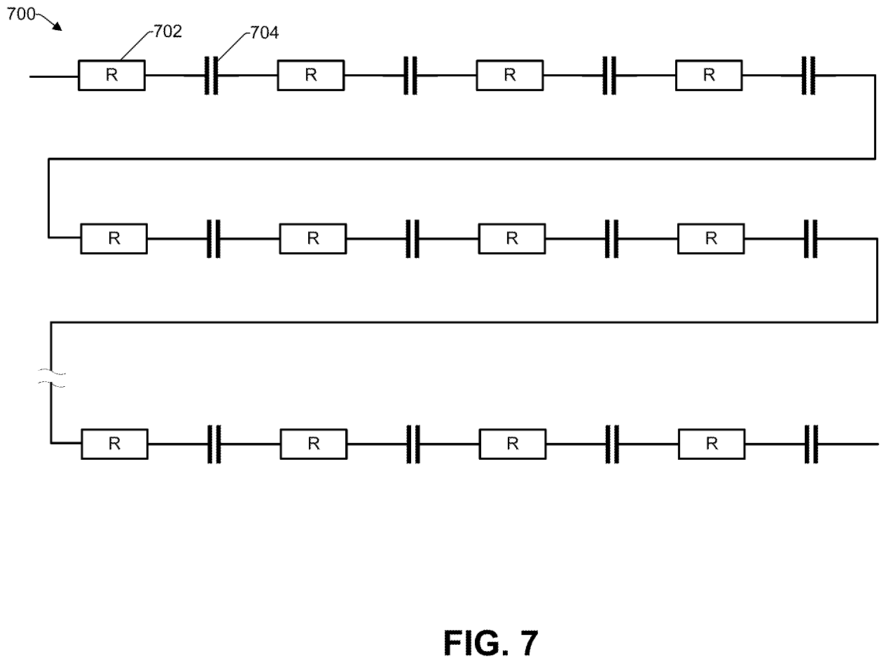

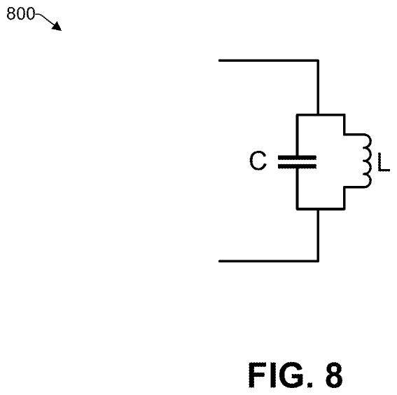

FIG. 7 is an alternative transmission cable 700 implemented as a series of capacitively coupled resonators, consistent with an illustrative embodiment. Transmission cable 700 includes a plurality of resonators (R) 702 that are coupled in series via capacitors (e.g., 704), resulting in a passband filter. By way of example and not limitation, FIG. 8 provides an example resonator 800, consistent with an illustrative embodiment. The example of FIG. 8 includes a capacitor and an inductor electrically coupled in parallel. Each resonator provides a lambda over 2 (2/2) cavity, sometimes referred to as a half-wavelength cavity, which is a type of resonant cavity that is half the wavelength of a particular electromagnetic signal. A resonator circuit is an electrical circuit that exhibits resonance, where the circuit responds to certain frequencies while suppressing others. As illustrated in FIG. 8, the basic components of a resonator circuit can include an inductor (L) and a capacitor (C) connected in parallel (or in series). The inductor stores energy in the form of a magnetic field, while the capacitor stores energy in the form of an electric field. When the inductance and capacitance are appropriately chosen, the circuit can resonate at a specific frequency determined by the values of the inductance and capacitance.

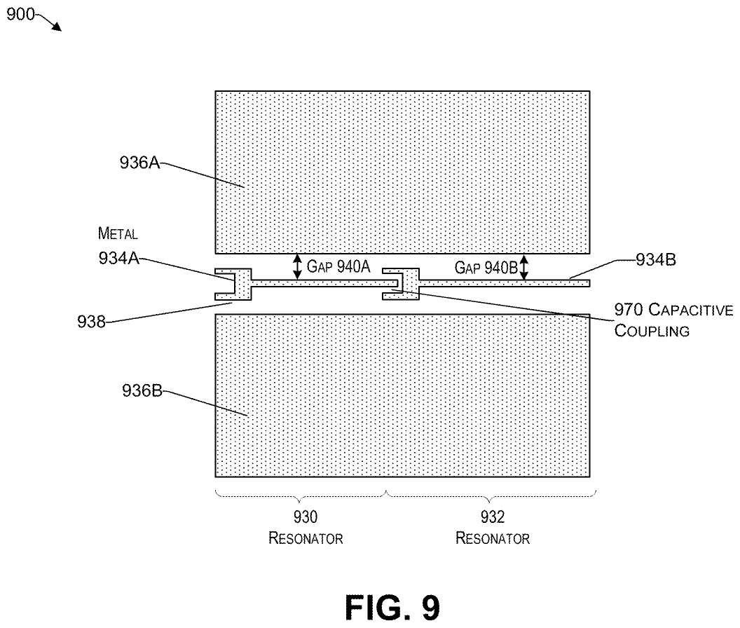

FIG. 9 provides a view of a portion of the cable 900 having two sections of having two sections of a cable interconnected via capacitive coupling, consistent with an illustrative embodiment. For example, there are two inner conductors 934A and 934B, which can be constructed of metal. There is a conducting shield 936A and 936B on each side (e.g., adjacent, above and below, or completely surrounding) the inner conductors 934A/B, which may be constructed of a metal. In one embodiment, the conducting shield 936A/B provides a reference ground shielding the inner conductors 934A/B.

The first resonator 930 has a gap 940A between the inner conductor 934A and the conducting shield 936A/B. Similarly, the second resonator 932 has a gap 940B between the inner conductor 934A and the conducting shield 936A/B. In one embodiment, the gaps 940A and 940B are equal. The inner conductor 934A is capacitively coupled 970 to the second inner conductor 934B. Stated differently the first and second resonators 930, 932 are capacitively coupled.

In one embodiment, the gap between the inner conductors 934A/B and the conducting shield 936A/B includes a dielectric. Accordingly, by adjusting the dimensions of each unit resonator (e.g., 930 or 932), appropriate impedance based on a capacitance (C) and an inductance (L) values can be achieved. The structure of the portion of the cable 900 can be repeated to achieve a predetermined length of a cable to implement a bandpass filter. In various embodiments, the architecture of FIG. 9 can be implemented, without limitation, as repeated segments of on chip transmission lines, waveguides, transmission lines on flexible substrates, etc.

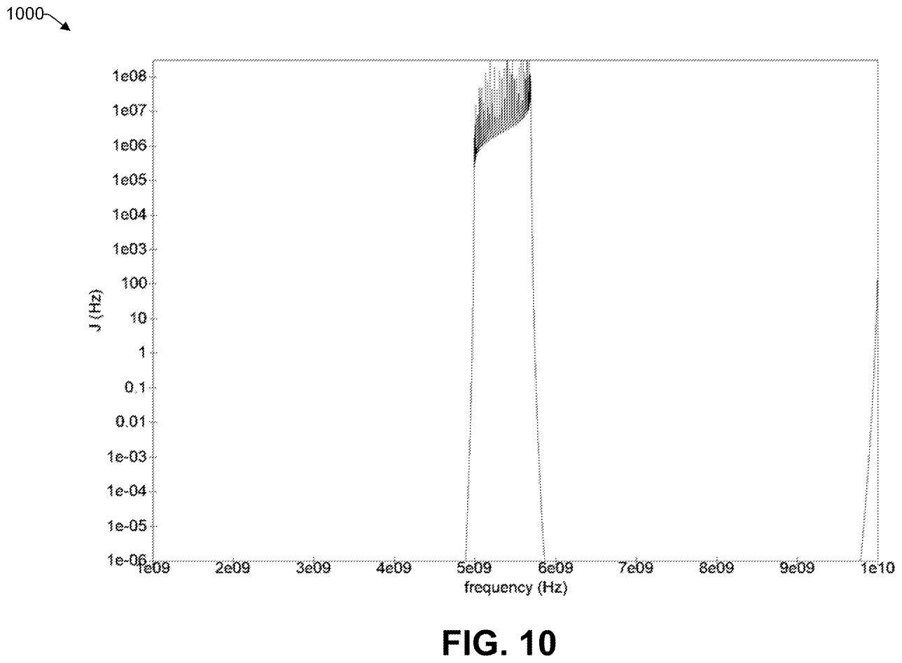

FIG. 10 provides a simulation result 1000 of a transmission cable, similar to the transmission cable 700 of FIG. 7, consistent with an illustrative embodiment. As illustrated, a passband is provided for a desired frequency range (e.g., 5 GHz to 6 GHz in the present example), while the signals outside the passband are substantially attenuated (e.g., by approximately 100 dB). In this way, components connected by the cable are protected from interference from any extraneous signals, as well as in reverse.

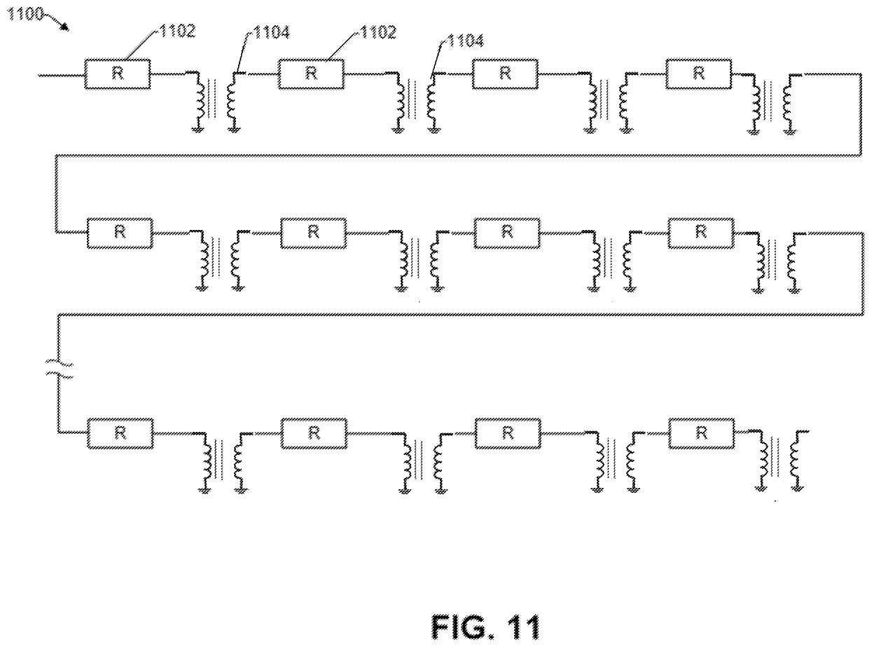

In yet another embodiment, the frequency response of a cable can be adjusted by using inductive coupling. In this regard, reference now is made to FIG. 11, which illustrates a transmission cable 1100 implemented as a periodic filter using inductance, consistent with an illustrative embodiment. The cable of FIG. 11 comprises a series connected resonant structures 1102 that are repeated at predetermined intervals. Between each resonant structure 1102, there is a mutual inductance or an inductance to ground 1104. The overall structure of the transmission cable 1100 results in a stepped impedance filter. The inductance provides a bandpass filtering effect that can be particularly useful for RF-SQUID based couplers.

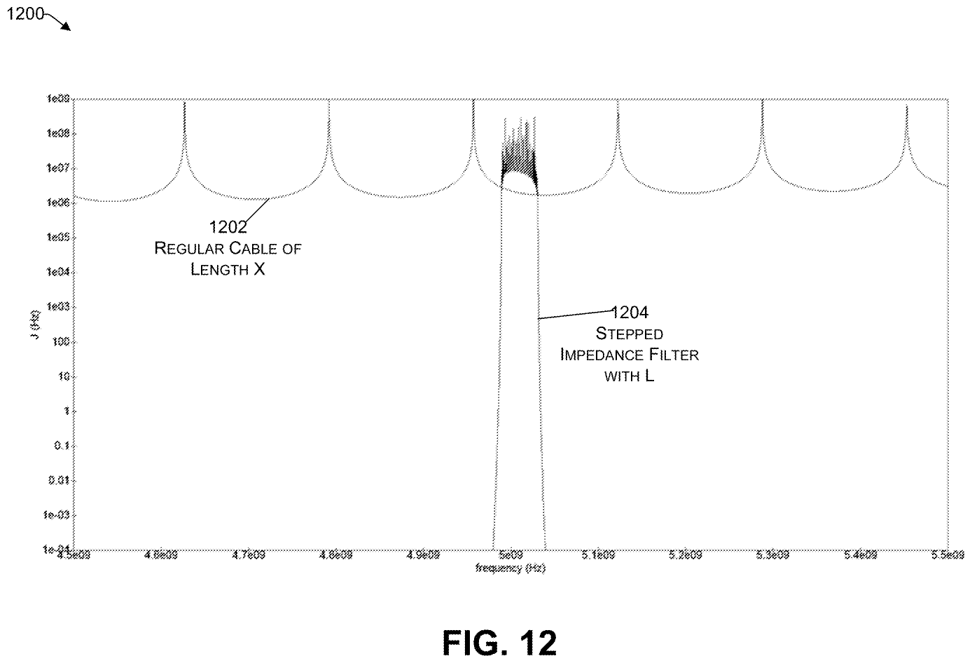

FIG. 12 provides simulation results 1200 of a frequency response of a regular transmission cable, as well as one similar to the transmission cable 1100 of FIG. 11, consistent with an illustrative embodiment. As illustrated, a regular cable 1202 having a predetermined length X does not provide any effective stop bands in its frequency response. By way of contrast, the cable implemented as stepped impedance filter 1204 having a same length X provides a passband at a predetermined frequency range. In the example of FIG. 12, the desired passband range is at approximately 4.97 GHz to 5.05 GHZ. Accordingly, the signals outside the passband are substantially attenuated. In this way, components connected by the cable are protected from interference from any extraneous signals (i.e., that are outside the passband range).

### Example Process

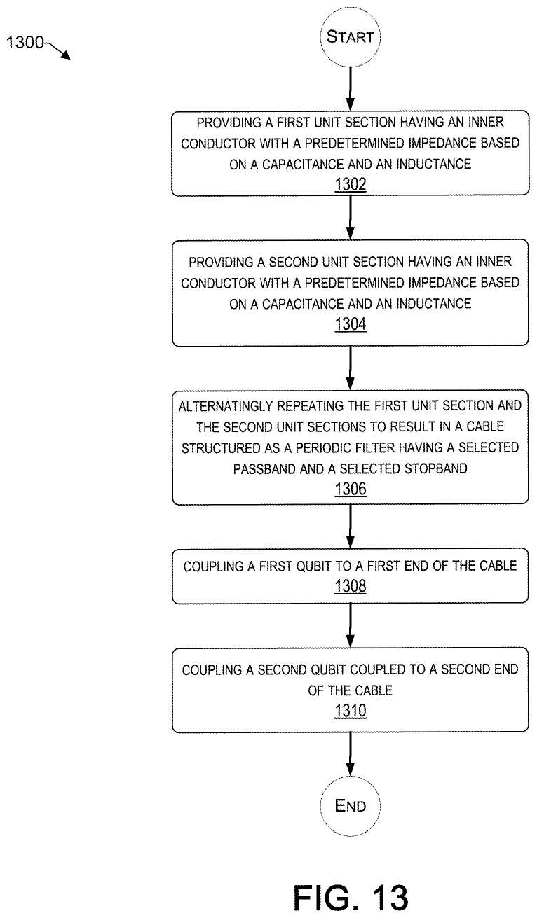

With the foregoing overview of the example architectures, it may be helpful now to consider a high-level discussion of an example process. To that end, FIG. 13 presents an illustrative process related to reading out signals from a quantum processor. Processes 1300 is illustrated as a collection of blocks, in a logical flowchart, which represents a sequence of operations that can be implemented in hardware, software, or a combination thereof. In the context of software, the blocks represent computer-executable instructions that, when executed by one or more processors, perform the recited operations. Generally, computer-executable instructions may include routines, programs, objects, components, data structures, and the like that perform functions or implement abstract data types. In each process, the order in which the operations are described is not intended to be construed as a limitation, and any number of the described blocks can be combined in any order and/or performed in parallel to implement the process.

At block 1302 a first unit section is provided, having an inner conductor with a predetermined impedance based on a capacitance and an inductance.

At block 1304, a second unit section is provided, having an inner conductor with a predetermined impedance based on a capacitance and an inductance is provided.

At block 1306, the first unit section and the second unit sections are alternatingly repeated and provide a cable structured as a periodic filter having a selected passband and a selected stopband.

At block 1308, a first qubit is coupled to a first end of the cable.

At block 1310, a second qubit is coupled to a second end of the cable.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

Aspects of the present disclosure are described herein with reference to a flowchart illustration and/or block diagram of a method, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. An interconnect system, comprising:
a first unit section having an inner conductor with a predetermined impedance based on a capacitance and an inductance; and
a second unit section having an inner conductor with a impedance based on a capacitance and an inductance,
wherein the first unit section and the second unit section are alternatingly repeated to result in a cable structured as a periodic filter having a selected passband and a selected stopband.

2. The interconnect system of claim 1, wherein each end of the cable is connected to a separate qubit.

3. The interconnect system of claim 2, wherein the separate qubits are on separate chips.

4. The interconnect system of claim 3, wherein the separate chips are in different cryogenic environments.

5. The interconnect system of claim 1, wherein the cable is a coaxial cable.

6. The interconnect system of claim 1, wherein:
the first unit section and second unit section each have a conducting shield; and
the inner conductor of the first unit section has a width that is smaller than a width of the inner conductor of the second unit section.

7. The interconnect system of claim 6, wherein the predetermined impedance of the inner conductor of the first unit section is lower than the predetermined impedance of the inner conductor of the second unit section.

8. The interconnect system of claim 1, wherein:
the cable forms a communications channel between two qubits; and
the cable provides an entanglement between the two qubits in the selected passband, while rejecting interference from other qubits in the selected stopband.

9. The interconnect system of claim 1, wherein the selected stopband covers a frequency range of one or more readout resonators coupled to separate qubits at each end of the cable.

10. The interconnect system of claim 1, wherein:
the first and second unit sections are different in structure; and
the alternately repeated first and second unit sections are configured as a stepped impedance filter.

11. The interconnect system of claim 1, wherein the first unit section has a gap, between the inner conductor and a conducting shield, that is larger than a gap between the inner conductor and the conducting shield of the second unit section.

12. The interconnect system of claim 1, wherein:
the first unit section and the second unit section have a same structure;
the first unit section and the second unit section are configured as a resonator;
the inner conductor of the first unit section is capacitively coupled to the inner conductor of the second unit section; and
the cable is a passband filter.

13. The interconnect system of claim 1, wherein:
the first unit section and the second unit section have a same structure;
the first unit section and the second unit section are each configured as a resonator;
the first unit section and the second unit section are inductively coupled; and
the cable is a passband filter.

14. A quantum communication link, comprising:
a first unit section having an inner conductor with a predetermined impedance based on a capacitance and an inductance;
a second unit section having an inner conductor with a predetermined impedance based on a capacitance, and an inductance, wherein the first unit section and the second unit section are alternatingly repeated to result in a cable structured as a periodic filter having a selected passband and a selected stopband;
a first qubit coupled to a first end of the cable; and
a second qubit coupled to a second end of the cable.

15. The quantum communication link of claim 14, wherein the first and second qubits are on separate chips.

16. The quantum communication link of claim 15, wherein the separate chips are in different cryogenic environments.

17. The quantum communication link of claim 14, wherein:
the first unit section and second unit section each have a conducting shield;
the inner conductor of the first unit section has a width that is smaller than a width of the second unit section; and
the predetermined impedance of the inner conductor of the first unit section is lower than the predetermined impedance of the inner conductor of the second unit section.

18. The quantum communication link of claim 14, wherein the cable provides an entanglement between the first qubit and the second qubit in the selected passband, while rejecting interference from other qubits in the selected stopband.

19. The quantum communication link of claim 14, wherein:
the first unit section and the second unit section have a same structure;
the first unit section and the second unit section are configured as a resonator;
the inner conductor of the first unit section is one of capacitively or inductively coupled to the inner conductor of the second unit section; and
the cable is a passband filter.

20. A method of providing a quantum communication link, comprising:
providing a first unit section having an inner conductor with a predetermined impedance based on a capacitance and an inductance;
providing a second unit section having an inner conductor with a predetermined impedance based on a capacitance and an inductance;
alternatingly repeating the first unit section and the second unit section to result in a cable structured as a periodic filter having a selected passband and a selected stopband;
coupling a first qubit to a first end of the cable; and
coupling a second qubit coupled to a second end of the cable.
